(19) United States
(12) Patent Application Publication
(10) Pub. No.: US 2023/0040390 A1
(43) Pub. Date: Feb. 9, 2023

(54) RADIATOR COATED WITH HEAT DISSIPATION LAYER, AND METHOD OF COATING RADIATOR

(71) Applicants: LG Electronics Inc., Seoul (KR); Korea University Research and Business Foundation, Seoul (KR)

(72) Inventors: Minwoo JEONG, Seoul (KR); Sehyeon KIM, Seoul (KR); Bongjun KIM, Seoul (KR); Wonjoon CHOI, Seoul (KR); Jaemin LEE, Gyeonggi-do (KR)

(21) Appl. No.: 17/791,627

(22) PCT Filed: Jan. 7, 2021
(86) PCT No.: PCT/KR2021/000173

§ 371 Date: Jul. 8, 2022

(30) Foreign Application Priority Data
Jan. 9, 2020 (KR) 10-2020-0003300

(51) Int. Cl. F28F 13/18; B05D 7/00; B05D 3/10; B05D 7/02; B05D 7/14

(52) U.S. Cl. CPC F28F 13/185; B05D 7/58; B05D 3/107; B05D 7/02; B05D 7/14; F28F 2255/20

(57) ABSTRACT

A radiator according to one embodiment of the present invention comprises at least one group of heat dissipation layers that are applied to the surface of the radiator so as to be sequentially layered thereon, wherein the one group of heat dissipation layer comprises a first coating layer formed by applying either a first dispersion solution or a second dispersion solution, and a second coating layer formed by applying the dispersion solution differing from that on the first coating layer, the first dispersion solution comprises positively charged metal oxide nanoparticles, and the second dispersion solution comprises negatively charged carbon nanotubes (CNT-COOH). The heat dissipation layer is formed in a porous thin film structure so as to have thickness of several micrometers, and thus increases a heat dissipation area by ten times, thereby improving heat dissipation efficiency, and can be applied without being restricted by the size, volume, shape, arrangement and the like of a radiator.

### TECHNICAL FIELD

The following description relates to a radiator coated with heat dissipation layers and a method of coating a radiator, and more particularly to a radiator and a method of coating a radiator, in which by applying a first dispersion containing positively charged metal oxide nanoparticles and a second dispersion containing carbon nanotubes with a negatively charged carboxyl group attached thereto, a surface of the radiator is coated in a stacked manner by self-assembly using electrostatic attraction, to form a heat dissipation layer having a porous thin film structure, thereby greatly improving heat dissipation performance.

### BACKGROUND ART

Generally, in order to prevent malfunction caused by heat generated in various parts of an electronic device during use, it is required to dissipate the generated heat. Methods of reducing heat generated by a heating element, such as the electronic device, may include a mechanical method of installing a small fan and the like, and a method of attaching a radiator, such as a heat sink, a heat pipe, etc., to the heating element to dissipate heat through a surface in contact with air.

A heat dissipation area dominantly affects heat dissipation by air convection in the heat sink and the like, such that in order to allow heat generated in devices or parts to be rapidly dissipated to the outside, a finned heat sink structure has been generally used, in which a plurality of heat dissipation fins uniformly protruding are arranged on an entire surface.

However, a process for manufacturing the heat sink, having a plurality of arranged heat dissipation fins, by an extrusion molding method using a mold is complicated, and in order to manufacture the heat sink in various shapes, a separate mold is required for each shape, thereby causing a problem of increasing processing costs. In addition, particularly a small electronic device has significant limitations in size, volume, arrangement, and shape, thereby limiting the increase in heat dissipation area.

In order to solve the above problems, there have been various techniques for increasing the heat dissipation area that contacts with air and enhancing heat dissipation performance by forming heat dissipation layers on a radiator, but the conventional methods may lead to a considerable increase in volume, with only slight improvement in heat dissipation area compared to the increase in volume.

### DISCLOSURE OF INVENTION

### Technical Problem

In order to solve the above problems, it is an object of embodiments of the present disclosure to provide a radiator capable of being produced in a simple manufacturing process and coated with a heat dissipation layer having a porous thin film structure, in which with an increase in thickness by about several micrometers, a heat dissipation area may be greatly improved.

In addition, it is another object of embodiments of the present disclosure to provide a heat dissipation layer capable of being easily coated regardless of volume, arrangement, shape, and the like of a radiator.

In addition, it is yet another object of embodiments of the present disclosure to provide a method of coating the radiator.

The objects of the present disclosure are not limited to the aforementioned objects and other objects not described herein will be clearly understood by those skilled in the art from the following description.

### Technical Solution

In order to achieve the above objects, a radiator according to a first embodiment of the present disclosure includes at least one set of heat dissipation layers which are sequentially stacked and coated on a surface of the radiator, wherein the set of heat dissipation layers comprise a first coating layer formed by applying either one of a first dispersion and a second dispersion, and a second coating layer formed by applying the other one of the dispersions to a surface of the first coating layer, wherein the first dispersion contains positively charged metal oxide nanoparticles, and the second dispersion contains negatively charged carbon nanotubes (CNT).

The metal oxide nanoparticles may be zinc oxide (ZnO) nanoparticles.

The carbon nanotubes may be multi-walled carbon nanotubes (MWCNT-COOH) to which a carboxyl group is attached.

A radiator according to a second embodiment of the present disclosure includes at least one set of heat dissipation layers which are sequentially stacked and coated on a surface of the radiator, wherein the set of heat dissipation layers include a first coating layer formed by applying either one of a first dispersion and a second dispersion, and a second coating layer formed by applying the other one of the dispersions to a surface of the first coating layer, wherein the first dispersion contains positively charged metal oxide nanoparticles, and the second dispersion contains negatively charged metal oxide nanoparticles.

A radiator according to a third embodiment of the present disclosure includes at least one set of heat dissipation layers which are sequentially stacked and coated on a surface of the radiator, wherein the set of heat dissipation layers include a first coating layer formed by applying either one of a first dispersion and a second dispersion, and a second coating layer formed by applying the other one of the dispersions to a surface of the first coating layer, wherein the first dispersion contains positively charged carbon nanotubes (CNT), and the second dispersion contains negatively charged metal oxide nanoparticles.

A method of coating a radiator according to an embodiment of the present disclosure includes: a first coating step of applying either one of a first dispersion and a second dispersion to a surface of the radiator to form a first coating layer; and a second coating step of applying the other one of the dispersions to form a second coating layer on the first coating layer, wherein the first dispersion contains positively charged metal oxide nanoparticles, and the second dispersion contains negatively charged carbon nanotubes (CNT-COOH).

The metal oxide nanoparticles may be zinc oxide (ZnO) nanoparticles.

The carbon nanotubes may be multi-walled carbon nanotubes (MWCNT-COOH) to which a carboxyl group is attached ( [symbol] [symbol] [symbol] ).

The method of coating a radiator ( [symbol] [symbol] [symbol] [symbol] ) may further include, after the first coating step, a first washing step of washing a residue, remaining after the coating, with deionized water.

The method of coating a radiator may further include, after the second coating step, a second washing step of washing a residue, remaining after the coating, with deionized water.

The method of coating a radiator may further include repeating the previously performed steps to achieve a required coating thickness.

Other detailed matters of the embodiments are included in the detailed description and the drawings.

### Advantageous Effects

According to embodiments of the present disclosure, one or more of the following effects may be provided.

First, heat dissipation layers of the present disclosure are stacked and coated to form a porous thin film structure, such that with almost no increase in thickness, a heat dissipation area may greatly increase.

Second, by coating a first dispersion and a second dispersion by self-assembly using electrostatic attraction, a coating process may be simplified.

Third, the heat dissipation layers not only have a thin film structure with a thickness of about several micrometers, but also are formed by allowing dispersions to flow through the layers or by immersing the layers in the dispersions, such that heat dissipation performance of the radiator may be improved with no limitations in size, volume, shape, arrangement, and the like of an electronic device, a heating element, and the radiator, thereby greatly improving the degree of freedom.

The effects of the present disclosure are not limited to the aforesaid, and other effects not described herein will be clearly understood by those skilled in the art from the following description of the appended claims.

### DESCRIPTION OF DRAWINGS

FIG. 1 is a cross-sectional view of an example of a flat plate heat sink on which heat dissipation layers are coated.

FIG. 2 is a cross-sectional view of an example of a finned heat sink on which heat dissipation layers are coated.

FIG. 3 is a cross-sectional view of an example of a heat pipe on which heat dissipation layers are coated.

FIG. 4 is a cross-sectional view of an example of a heat sink which is disposed on a heat pipe, and on which heat dissipation layers are coated.

FIG. 5 is an enlarged view of images of heat dissipation layers according to an embodiment of the present disclosure.

FIG. 6 is a view of images for explaining experiments according to an embodiment of the present disclosure.

FIG. 7 is a flowchart explaining a method of coating a radiator according to an embodiment of the present disclosure.

### BEST MODE FOR CARRYING OUT THE INVENTION

Hereinafter, the present disclosure will be described in detail with reference to the accompanying drawings, in which the same reference numerals are used throughout the drawings to designate the same or similar components, and a redundant description thereof will be omitted. Further, the accompanying drawings are used to help easily understand various technical features and it should be understood that the embodiments presented herein are not limited by the accompanying drawings. As such, the present disclosure should be construed to extend to any alterations, equivalents and substitutes in addition to those which are particularly set out in the accompanying drawings.

It will be understood that, although the terms first, second, etc., may be used herein to describe various elements, these elements should not be limited by these terms. These terms are only used to distinguish one element from another.

As used herein, the singular forms are intended to include the plural forms as well, unless the context clearly indicates otherwise.

It should be understood that the terms “comprise”, ‘include”, “have”, etc. when used in this specification, specify the presence of stated features, integers, steps, operations, elements, components, or combinations thereof but do not preclude the presence or addition of one or more other features, integers, steps, operations, elements, components, or combinations thereof.

A radiator is attached to a heating element, such as an electronic device and the like, and has a heat dissipation structure for dissipating heat generated by the heating element through a surface in contact with air, and examples of the radiator include a flat plate heat sink having a flat plate shape, a finned heat sink having a plurality of radiation fins arranged therein, a heat pipe, and the like. The heat pipe is a pipe for heat dissipation by transferring heat, generated by the heating element, to another object, and may serve as a radiator in itself, or may transfer heat to another radiator for heat dissipation.

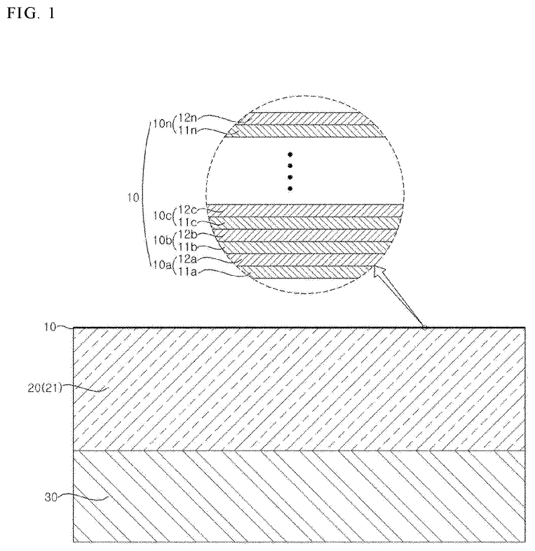

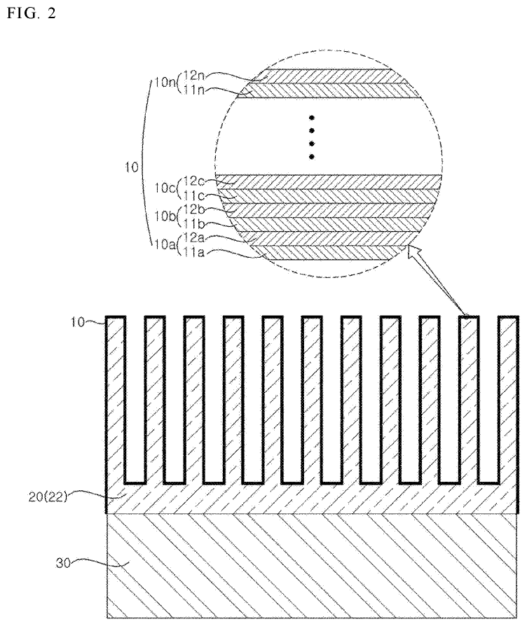

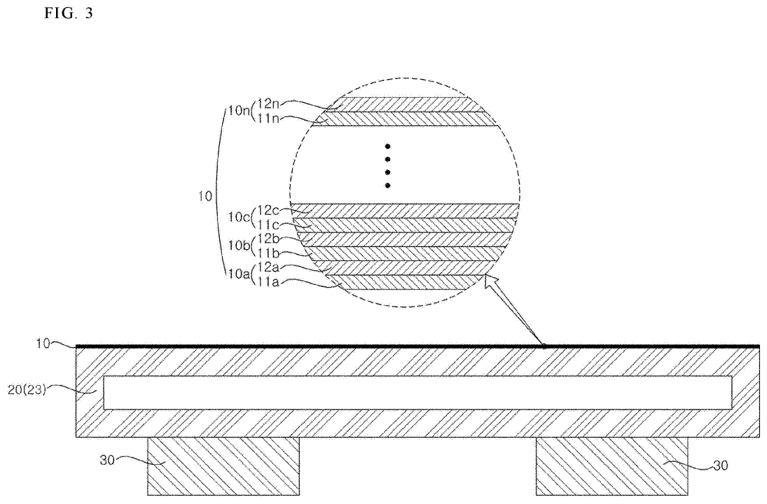

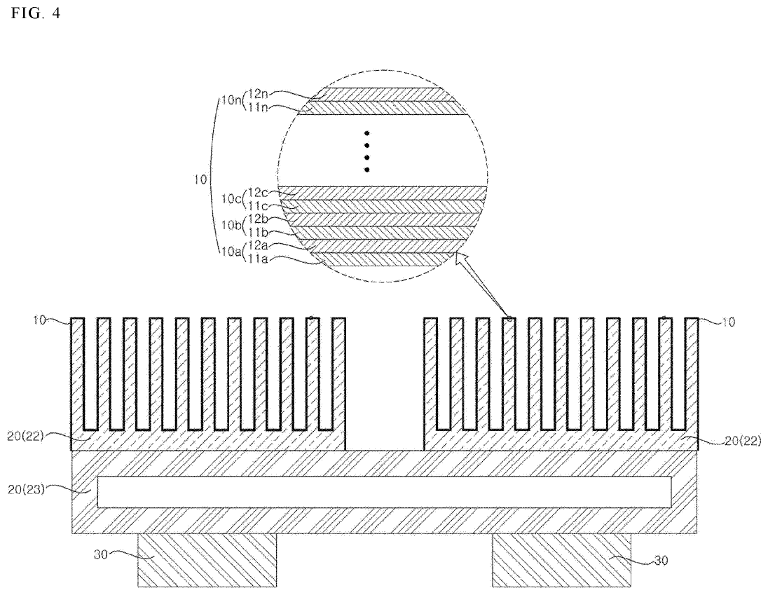

FIGS. 1 to 4 are cross-sectional views of examples of various radiators 20 on which heat dissipation layers of the present disclosure are formed.

Referring to FIGS. 1 to 4, in a radiator according to an embodiment of the present disclosure, at least one set of heat dissipation layers 10 may be stacked and coated on a surface of the radiator 20. In this case, the radiator 20 has a structure for dissipating heat from a heat source, and is not limited to a particular shape and may include various shapes of a flat plate heat sink 21, a finned heat sink 22, a heat pipe 23, and the like.

The one set of heat dissipation layers 10 may include a first coating layer 11 formed by applying either one of a first dispersion and a second dispersion, and a second coating layer 12 formed on the first coating layer by applying the other one of the dispersions.

In a first embodiment, the first dispersion may contain positively charged metal oxide nanoparticles, and the second dispersion may contain negatively charged carbon nanotubes (CNT).

In a second embodiment, the first dispersion may contain positively charged metal oxide nanoparticles, and the second dispersion may contain negatively charged metal oxide nanoparticles.

In a third embodiment, the first dispersion may contain positively charged carbon nanotubes (CNT), and the second dispersion may contain negatively charged metal oxide nanoparticles.

The first coating layer 11 and the second coating layer 12 are bonded and stacked by self-assembly using electrostatic attraction between different charges, to form a set of heat dissipation layers 10. The heat dissipation layers 10 have a porous thin film structure, in which with an increase in thickness by about several micrometers, a heat dissipation area may increase dozens of times.

Hereinafter, the first dispersion will be described.

Nanoparticles are ultrafine particles with at least one dimension of 100 nm, i.e., one ten-millionth of a meter or less. The metal oxide nanoparticles, in which metal oxides are combined in nano size, have different properties from typical metal oxides.

The metal oxide nanoparticles may be preferably Zinc Oxide (ZnO) nanoparticles. Various methods of synthesizing ZnO nanoparticles which have been reported up to date include a hydrothermal method, a sol gel method, a physical-chemical deposition method, a chemical solution deposition method, an electrochemical deposition method, etc., and commercially available metal oxide nanoparticles were used in the present disclosure.

In the embodiment of the present disclosure, the first dispersion was obtained by dispersing the metal oxide nanoparticles in deionized water using an ultrasonicator. There are various known methods of dispersing the metal oxide nanoparticles to obtain the dispersion, such that the present disclosure is not limited to the dispersion method of using the ultrasonicator.

By surface modification, the zinc oxide nanoparticles may have positive charge characteristics by adsorbing ions having positive charges on their surface with the Zeta potential of the dispersion, or may have negative charge characteristics by adsorbing ions having negative charges, which are commonly called a dispersion of positively charged zinc oxide nanoparticles or a dispersion of negatively charged zinc oxide nanoparticles. The property of adsorbing positively charged or negatively charged ions may vary depending on the hydrogen ion concentration (pH) of a dispersion.

The dispersion of positively charged metal oxide nanoparticles is not limited to the dispersion of positively charged zinc oxide nanoparticles, and any dispersion of positively charged metal oxide nanoparticles may be used as long as the metal oxide nanoparticles may have positive charge characteristics or negative charge characteristics by adsorbing ions having positive or negative charges on their surface with the Zeta potential, while maintaining the shape of nanoparticles.

Hereinafter, the second dispersion will be described.

A carbon nanotube (CNT) is a carbon allotrope having a cylinder-shaped nanostructure. Carbon nanomaterials have advantages of both nanomaterials and organic materials, with the nanomaterials being advantageous in providing a wide surface area and shortening a transfer path to facilitate mass transfer, etc., and the organic materials being advantageous in controlling physical properties using various chemical properties of the organic materials and having competitive price, such that the carbon nanomaterials are useful in various fields, such as nano technology, electrical engineering, optical science, materials engineering, and the like. Particularly, the carbon nanomaterials have unique mechanical and electrical properties, and thus are used as additives for various structure materials.

The types of carbon nanotube include a single-walled carbon nanotube (SWCNT), a double-walled carbon nanotube (DWCNT), a multi-walled carbon nanotube (MWCNT), and the like. It is known that the single-walled carbon nanotube has a specific surface area of up to about 1,000 m2/g, and the SWCNT and DWCNT show a wider specific surface area than the MWCNT, but have a drawback in that the SWCNT and DWCNT are relatively difficult to manufacture and are expensive.

The carbon nanotube may be surface modified such that a functional group may be attached to its surface. In this case, the carbon nanotube may have positive charge characteristics or negative charge characteristics depending on the functional group.

For example, by treating the carbon nanotube with acid using sulfuric acid and nitric acid for surface modification of the carbon nanotube, a negatively charged carboxyl group (—COOH) is formed on the surface of the carbon nanotube. Then, the second dispersion is prepared by dispersing the carbon nanotube (CNT-COOH), having the negatively charged carboxyl group attached to its surface, in deionized water using an ultrasonicator. There are various known methods of dispersing nanoparticles to obtain the dispersion, such that the present disclosure is not limited to the dispersion method of using the ultrasonicator.

In another example, a positively charged amine group (—NH₂, NHR, or NR₂) may be attached to the surface of the carbon nanotube.

A surface to be coated of the radiator may be formed of a metal or polymer material. The first coating layer 11, which is first coated on the surface to be coated, may be formed by applying either one of the first dispersion and the second dispersion. In this case, in order to allow the first coating layer 11 to be bonded to the surface to be coated by self-assembly using electrostatic attraction, the surface to be coated is preferably formed of a metal or polymer material in which electrons move freely or polarization easily occurs.

At least one set of heat dissipation layers 10 may be stacked on the surface of the radiator 20. That is, one set of heat dissipation layers 10 may be stacked on the surface of the radiator, but a plurality of sets of heat dissipation layers 10 may be stacked thereon in order to increase a heat dissipation area to achieve required heat dissipation performance. In this case, the respective heat dissipation layers 10a, 10b, . . . , and 10n include first coating layers 11a, 11b, . . . , and 11n and second coating layers 12a, 12b, . . . , and 12n.

A first coating layer 11n of an nth heat dissipation layer 10n may be combined with a second coating layer 12n-1 of an n−1th heat dissipation layer 10n-1 by self-assembly using electrostatic attraction, to be stacked and coated. For example, the first coating layer 11b of the second heat dissipation layer 10b may be combined with the second coating layer 12a by self-assembly using electrostatic attraction, to be stacked and coated.

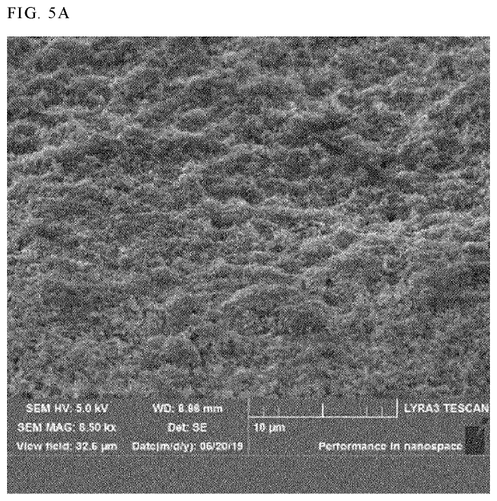

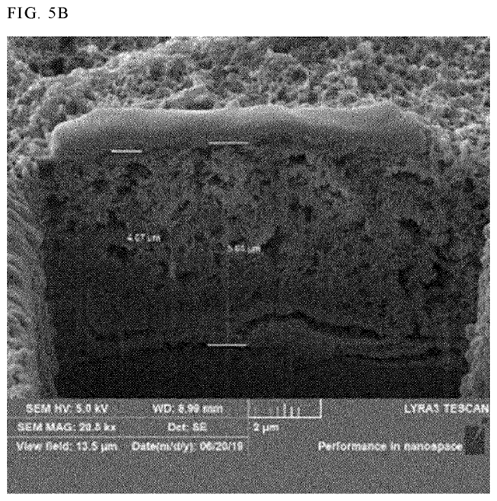

FIG. 5 is an enlarged view of images of heat dissipation layers according to an embodiment of the present disclosure.

FIG. 5 illustrates surfaces and cross-sections of 20 heat dissipation layers 10 which are observed by a scanning electron microscope (SEM), and positively charged Zinc Oxide nanoparticles (ZnO nanoparticles) were used in the first dispersion, and multi-walled carbon nanotubes (MWCNT-COOH) with a negatively charged carboxyl group were used in the second dispersion. Referring to the images in FIG. 5, it can be seen that the heat dissipation layers 10 have a porous structure, in which with an increase in thickness by about 0.25 μm per set of heat dissipation layers 10, a surface area may increase several times, and when 20 heat dissipation layers are stacked, with an increase in thickness by about 5 μm, the surface area may increase 50 times.

The heat dissipation layers are formed by self-assembly by contacting with the dispersions, and with a small increase in thickness by about several micrometers, a heat dissipation area is expected to increase dozens of times, such that, as in the case of a small electronic device, even when there are limitations in increasing a volume or modifying a shape in order to increase the heat dissipation area, heat dissipation performance may be improved regardless of the limitations.

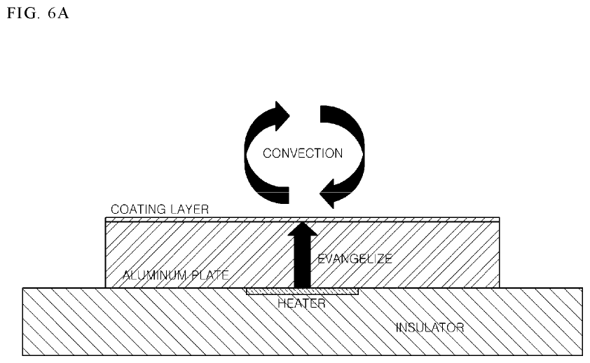

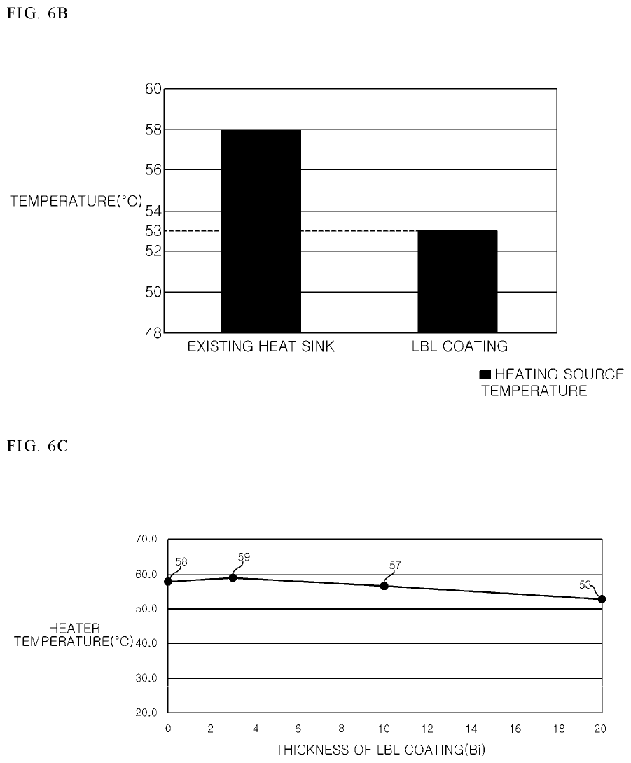

FIG. 6 is a view of images for explaining experiments according to an embodiment of the present disclosure.

Referring to FIG. 6A, the experiment was conducted in which a heating element 30 was placed at a lower central portion of a flat aluminum plate (flat plate heat sink), and an upper surface of the aluminum plate was coated with a heat dissipation layer according to an embodiment of the present disclosure.

In this case, coating was performed by using positively charged zinc oxide nanoparticles (ZnO nanoparticles) in the first dispersion, and multi-walled carbon nanotubes (MWCNT-COOH) with a negatively charged carboxyl group in the second dispersion.

In addition, an insulator was disposed at a lower part of the heating element 30, so as to transfer convective heat only to an upper part thereof. In order to determine a change in thermal resistance for conduction and thermal resistance for convection, temperature was measured by attaching a temperature sensor to the heating element 30 and the coating layers.

In the experiment, temperature of the heating element 30 was compared between an uncoated general aluminum plate and an aluminum plate on which the heat dissipation layers 10 are stacked and coated, in which the comparison was performed after the heat dissipation layers 10 are stacked and coated in sets one by one.

Referring to FIGS. 6B and 6C, when zero to three heat dissipating layers 10 were stacked, no significant change in heat dissipation performance was observed, but a gradual decrease in temperature of the heating element 30 was observed from the time when four layers were stacked.

When 20 heat dissipation layers 10 were stacked, the temperature of the heat dissipation layers 10 decreased by about 5° C. with an increase in thickness by about 5 μm, as compared to the case where the heat dissipation layers 10 were not coated, and no significant change in thermal resistance for conduction was observed, but a decrease in thermal resistance for convection by about 20% was observed.

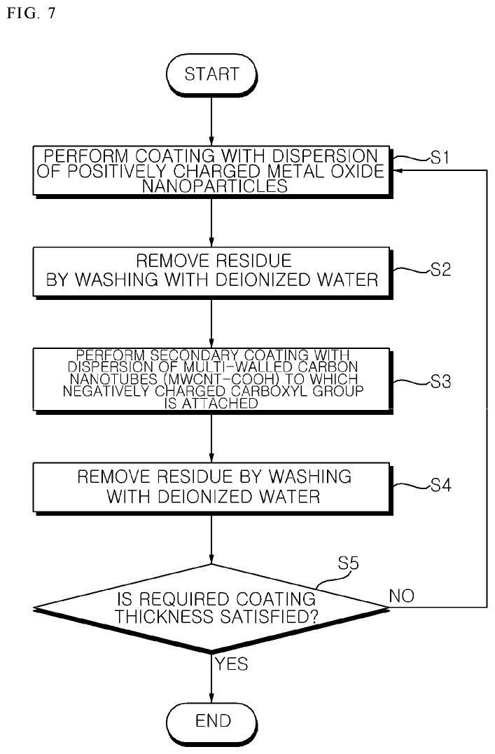

FIG. 7 is a flowchart explaining a method of manufacturing a radiator according to an embodiment of the present disclosure.

According to a first embodiment, a surface to be coated is first coated with a first dispersion in which positively charged metal oxide nanoparticles are dispersed (S1).

The surface to be coated may be brought into contact with the first dispersion by allowing the first dispersion to flow over the surface to be coated or by immersing the surface to be coated in the first dispersion. When the first dispersion is in contact with the surface to be coated which is made of metal or polymer, negative charges in the metal or polymer are accumulated on the contact surface due to electrostatic attraction with the positively charged metal oxide nanoparticles in the first dispersion, and when positive and negative charges meet, the force of attraction acts therebetween, such that dispersion and the surface are combined and stacked by self-assembly, to form the first coating layer 11.

When about five minutes elapse after the first coating layer 11 is formed, a residual solution remaining after coating, a foreign material, etc., which remain on the surface, are washed with deionized water (S2).

If the residual solution, remaining after coating, and the foreign material remain on the surface, the electrostatic attraction between the first coating layer 11 and the second coating layer 12 may be weakened, such that it is preferable to wash residual ions that have not been bonded, and foreign materials.

After a surface of the first coating layer is washed with the deionized water, the second dispersion, in which the carbon nanotubes (CNT-COOH) with the negatively charged carboxyl group attached thereto are dispersed, is applied to the surface of the first coating layer 11 to be stacked and coated (S3).

As in S1, by allowing the second dispersion to flow over the surface to be coated of the first coating layer 11 or by immersing the surface to be coated in the second dispersion, the surface to be coated may be brought into contact with the first dispersion. When the second dispersion is in contact with the first coating layer 11 formed of a positively charged metal oxide, positive charges in the first coating layer 11 are accumulated on the contact surface due to electrostatic attraction with the carbon nanotubes (CNT-COOH) to which the negatively charged carboxyl group is attached, in the second dispersion, and when positive and negative charges meet, the force of attraction acts therebetween, such that the dispersion and the surface are combined and stacked by self-assembly, to form the second coating layer 12 on top of the first coating layer.

When about five minutes elapse after the second coating layer 12 is formed on the first coating layer 11, a residual solution remaining after coating, a foreign material, etc., which remain on the surface, are washed with deionized water (S4).

When the residual solution, remaining after coating, and the foreign material remain on the surface, if a plurality of heat dissipation layers 10 are stacked by repeating the above steps, the electrostatic attraction between the second coating layer 12 and the first coating layer 11 stacked and coated on the second coating layer may be weakened, such that it is preferable to wash residual ions that have not been bonded, and foreign materials. In this manner, the first coating layer 11 and the second coating layer 12 are combined to form a single heat dissipation layer 10.

If the heat dissipation layer 10 does not satisfy a thickness required for heat dissipation performance, the previous steps may be repeated, and if the heat dissipation layer 10 satisfies the required thickness, the process may be terminated (S5). By repeating the previous steps, a plurality of sets of heat dissipation layers 10 may be stacked and coated on the surface to be coated, thereby increasing a heat dissipation area, and achieving required heat dissipation performance.

According to a second embodiment, coating is performed in S1 with the first dispersion in which the positively charged metal oxide nanoparticles are dispersed, and coating is performed in S3 with the second dispersion in which the negatively charged metal oxide nanoparticles are dispersed.

According to a third embodiment, coating is performed in S1 with the first dispersion in which the positively charged carbon nanotubes (CNT) are dispersed, and coating is performed in S3 with the second dispersion in which the negatively charged metal oxide nanoparticles are dispersed.

The aforementioned steps S1 and S3 may be performed in reverse order. That is, the surface to be coated may be first coated with the second dispersion by self-assembly to form the first coating layer 11, followed by deionization, and then the first dispersion may be applied to the surface of the first coating layer 11 to form the second coating layer 12, followed by deionization again to form the single heat dissipation layer 10, and by repeating the steps, the plurality of sets of heat dissipation layers 10 may be stacked and coated on the surface to be coated.

1-15. (canceled)

16. A radiator configured to dissipate heat, the radiator comprising:
a plurality of heat dissipation layers that are stacked and coated on a surface of the radiator,
wherein the plurality of heat dissipation layers comprise:
a first coating layer formed by applying either one of a first dispersion or a second dispersion, and
a second coating layer disposed on the first coating layer and defined by the other one of the first dispersion or the second dispersion to a surface of the first coating layer, and
wherein the first dispersion includes metal oxide nanoparticles that are positively charged, and the second dispersion includes carbon nanotubes (CNT) that are negatively charged.

17. The radiator of claim 16, wherein the metal oxide nanoparticles comprise zinc oxide (ZnO) nanoparticles.

18. The radiator of claim 16, wherein the carbon nanotubes comprise multi-walled carbon nanotubes (MWCNT) and a carboxyl group (COOH) attached to the MWCNT.

19. The radiator of claim 16, wherein the surface of the radiator is made of a metal material or a polymer material.

20. The radiator of claim 19, wherein the first coating layer is in contact with the surface of the radiator.

21. The radiator of claim 16, wherein the plurality of heat dissipation layers further comprise:
a plurality of first coating layers including the first coating layer; and
a plurality of second coating layers including the second coating layer, and
wherein the plurality of first coating layers and the plurality of second coating layers are alternately stacked such that each of the plurality of first coating layers is disposed between two of the plurality of second coating layers, or each of the plurality of second coating layers is disposed between two of the plurality of first coating layers.

22. A radiator configured to dissipate heat, the radiator comprising:
a plurality of heat dissipation layers that are stacked and coated on a surface of the radiator,
wherein the plurality of heat dissipation layers comprise:
a first coating layer defined by either one of a first dispersion or a second dispersion, and
a second coating layer disposed on the first coating layer and defined by the other one of the first dispersion or the second dispersion to a surface of the first coating layer, and
wherein the first dispersion includes metal oxide nanoparticles that are positively charged, and the second dispersion includes metal oxide nanoparticles that are negatively charged.

23. The radiator of claim 22, wherein the first coating layer is in contact with the surface of the radiator.

24. The radiator of claim 22, wherein the plurality of heat dissipation layers further comprise:
a plurality of first coating layers including the first coating layer; and
a plurality of second coating layers including the second coating layer, and
wherein the plurality of first coating layers and the plurality of second coating layers are alternately stacked such that each of the plurality of first coating layers is disposed between two of the plurality of second coating layers, or each of the plurality of second coating layers is disposed between two of the plurality of first coating layers.

25. A radiator configured to dissipate heat, the radiator comprising:
a plurality of heat dissipation layers that are stacked and coated on a surface of the radiator,
wherein the plurality of heat dissipation layers comprise:
a first coating layer defined by either one of a first dispersion or a second dispersion, and
a second coating layer defined by the other one of the first dispersion or he second dispersion to a surface of the first coating layer, and
wherein the first dispersion includes carbon nanotubes (CNT) that are positively charged, and the second dispersion includes metal oxide nanoparticles that are negatively charged.

26. The radiator of claim 25, wherein the plurality of heat dissipation layers further comprise:
a plurality of first coating layers including the first coating layer; and
a plurality of second coating layers including the second coating layer, and
wherein the plurality of first coating layers and the plurality of second coating layers are alternately stacked such that each of the plurality of first coating layers is disposed between two of the plurality of second coating layers, or each of the plurality of second coating layers is disposed between two of the plurality of first coating layers.

27. A method for coating a heat dissipation layer on a radiator, the method comprising:
applying either one of a first dispersion or a second dispersion to a surface of the radiator to thereby define a first coating layer; and
applying the other one of the first dispersion or the second dispersion to a surface of the first coating layer to thereby define a second coating layer on the first coating layer,
wherein the first dispersion includes metal oxide nanoparticles that are positively charged, and the second dispersion includes carbon nanotubes (CNT) that are negatively charged.

28. The method of claim 27, wherein the metal oxide nanoparticles comprise zinc oxide (ZnO) nanoparticles.

29. The method of claim 27, wherein the carbon nanotubes comprise multi-walled carbon nanotubes (MWCNT) and a carboxyl group (COOH) attached to the MWCNT.

30. The method of claim 27, further comprising:
washing the first coating layer with deionized water to thereby remove a residue.

31. The method of claim 30, further comprising:
washing the second coating layer with deionized water to thereby remove a residue.

32. The method of claim 31, further comprising:
repeating (i) applying either one of the first dispersion or the second dispersion, (ii) washing with deionized water, (iii) applying the other one of the first dispersion or the second dispersion, and (iv) washing with deionized water until the heat dissipation layer has a predetermined coating thickness.

33. The method of claim 27, wherein the first coating layer or the second coating layer is coated on a surface of the radiator that is made of a metal material or a polymer material.

34. The method of claim 27, wherein the second dispersion further includes metal oxide nanoparticles that are negatively charged.

35. The method of claim 27, wherein:
the first dispersion further includes carbon nanotubes (CNT) that are positively charged; and
the second dispersion further includes metal oxide nanoparticles that are negatively charged.
